(19) United States
(12) Patent Application Publication
(10) Pub. No.: US 2013/0203204 A1
(43) Pub. Date: Aug. 8, 2013

(54) METHOD FOR MANUFACTURING FLEXIBLE SOLAR BATTERY MODULE

(71) Applicants: Hiroshi Hiraike, Osaka (JP); Masahiro Asuka, Osaka (JP); Kiyomi Uenomachi, Osaka (JP); Takahiro Nomura, Osaka (JP); Jiamo Guo, Osaka (JP); Takahiko Sawada, Osaka (JP)

(72) Inventors: Hiroshi Hiraike, Osaka (JP); Masahiro Asuka, Osaka (JP); Kiyomi Uenomachi, Osaka (JP); Takahiro Nomura, Osaka (JP); Jiamo Guo, Osaka (JP); Takahiko Sawada, Osaka (JP)

(73) Assignee: Sekisui Chemical Co., td., Osaka (JP)

(21) Appl. No.: 13/821,625

(22) PCT Filed: Sep. 20, 2011
(86) PCT No.: PCT/JP2011/071361

§ 371 Date: Apr. 24, 2013

(30) Foreign Application Priority Data
Sep. 22, 2010 (JP) 2010-212714
Sep. 30, 2010 (JP) 2010-223104

(51) Int. Cl. H01L 31/0203

(52) U.S. Cl. CPC H01L 31/0203
USPC 438/64

(57) ABSTRACT

An object of the present invention is to provide a method for producing a flexible solar cell module which makes it possible to encapsulate a solar cell in a continuous manner without the need to perform a crosslinking process and highly efficiently produce flexible solar cell modules in which a solar cell and a solar cell encapsulant sheet are well adhered to each other without causing wrinkles and curls. The present invention is a method for producing a flexible solar cell module, including thermocompression bonding of a solar cell encapsulant sheet to at least a light-receiving surface of a solar cell element that includes a flexible substrate and a photoelectric conversion layer on the flexible substrate by pressing the solar cell encapsulant sheet and the solar cell element together between a pair of heating rolls, the solar cell encapsulant sheet including a fluoropolymer sheet and an adhesive layer on the fluoropolymer sheet, the adhesive layer including an ethylene-glycidyl methacrylate copolymer resin, the ethylene-glycidyl methacrylate copolymer resin including 5 to 10% by weight of glycidyl methacrylate units.

### TECHNICAL FIELD

The present invention relates to a method for producing a flexible solar cell module which makes it possible to encapsulate a solar cell element in a continuous manner without the need to perform a crosslinking process and highly efficiently produce flexible solar cell modules in which a solar cell element and a solar cell encapsulant sheet are well adhered to each other without causing wrinkles and curls.

### BACKGROUND ART

Solar cell modules known so far are: rigid solar cell modules that include a glass substrate; and flexible solar cell modules that include a thin film substrate of stainless steel or a substrate made of a heat resistant polymer material such as polyimide or polyester. In recent years, flexible solar cell modules have been attracting attention because they are easy to transport and install due to their thin and lightweight designs, and have high impact resistance.

A flexible solar cell module is a laminate of a flexible solar cell element and solar cell encapsulant sheets encapsulating the upper and lower surfaces of the flexible solar cell element. The flexible solar cell element is a laminate created by stacking, on a flexible substrate, a thin layer such as a photoelectric conversion layer made of a silicon semiconductor, a compound semiconductor, or the like which generates a current when exposed to light.

The solar cell encapsulant sheets serve to mitigate impacts from the exterior and protect the solar cell element from corrosion, and consist of a transparent sheet and an adhesive layer on the transparent sheet. The adhesive layers, which are designed to encapsulate the solar cell element, have been made using ethylene-vinyl acetate (EVA) resins (for example, Patent Literature 1).

The use of EVA resins, however, has some problems such as an extended production time and generation of an acid because it requires a crosslinking process. In view of these problems, some attempts have been made to form an adhesive layer of a solar cell encapsulant sheet using a non-EVA resin such as a silane-modified olefin resin (for example, Patent Literature 2).

Flexible solar cell modules have been conventionally produced by a method involving cutting a flexible solar cell element and solar cell encapsulant sheets into desired shapes, stacking the cut pieces, and bonding them together into an integrated laminate in a static state by vacuum laminating. Such vacuum laminating methods take a long time to finish bonding, and therefore are disadvantageously less efficient in producing solar cell modules.

One of methods for producing a flexible solar cell module under study is roll-to-roll processing that is advantageous for mass production (for example, Patent Literature 3).

The roll-to-roll processing is a technique to produce a flexible solar cell module in a continuous manner, and uses a roll of a solar cell encapsulatant film sheet. The solar cell encapsulant sheet is unrolled, and subjected to thermocompression bonding in which the solar cell encapsulant sheet is pressed together with a solar cell element between a pair of rolls to encapsulate the solar cell element.

The roll-to-roll processing is expected to enable continuous and remarkably efficient production of flexible solar cell modules.

However, the roll-to-roll processing, when used to produce a flexible solar cell module by encapsulating a flexible solar cell element with a conventional solar cell encapsulant sheet, causes some problems that strikingly reduce the production efficiency, such as the need to perform a crosslinking process and occurrence of wrinkles and curls upon thermocompression bonding of the flexible solar cell element and the solar cell encapsulant sheet between rolls, and other problems such as insufficient adhesion between the flexible solar cell element and the solar cell encapsulant sheet.

In this context, there has been a demand for a method that maintains the high production efficiency of the roll-to-roll processing enough, prevents wrinkles and curls, and allows a flexible solar cell element to be well encapsulated in a continuous manner.

### CITATION LIST

### Patent Literature

Patent Literature 1: Japanese Kokai Publication No. Hei-07-297439 (JP-A H07-297439)
Patent Literature 2: Japanese Kokai Publication No. 2004-214641 (JP-A 2004-214641)
Patent Literature 3: Japanese Kokai Publication No. 2000-294815 (JP-A 2000-294815)

### SUMMARY OF INVENTION

### Technical Problem

In view of the above-mentioned situation, the present invention provides a method for producing a flexible solar cell module which makes it possible to encapsulate a solar cell element in a continuous manner without the need to perform a crosslinking process and highly efficiently produce flexible solar cell modules in which a solar cell element and a solar cell encapsulant sheet are well adhered to each other without causing wrinkles and curls.

### Solution to Problem

The present invention 1 is a method for producing a flexible solar cell module, including thermocompression bonding of a solar cell encapsulant sheet to at least a light-receiving surface of a solar cell element that includes a flexible substrate and a photoelectric conversion layer on the flexible substrate by pressing the solar cell encapsulant sheet and the solar cell element together between a pair of heating rolls,

the solar cell encapsulant sheet including a fluoropolymer sheet and an adhesive layer on the fluoropolymer sheet, the adhesive layer including an ethylene-glycidyl methacrylate copolymer,

the ethylene-glycidyl methacrylate copolymer including 5 to 10% by weight of glycidyl methacrylate units.

The present invention 2 is a method for producing a flexible solar cell module, including thermocompression bonding of a solar cell encapsulant sheet to at least a light-receiving surface of a solar cell element that includes a flexible substrate and a photoelectric conversion layer on the flexible substrate by pressing the solar cell encapsulant sheet and the solar cell element together between a pair of heating rolls,

the solar cell encapsulant sheet including a fluoropolymer sheet and an adhesive layer on the fluoropolymer sheet, the adhesive layer including an ethylene-acrylic acid ester-maleic anhydride ternary copolymer,

the ethylene-acrylic acid ester-maleic anhydride ternary copolymer including: 71 to 93% by weight of ethylene units; 5 to 28% by weight of acrylic acid ester units; and 0.1 to 4% by weight of maleic anhydride units.

The following description is offered to illustrate the present invention in detail.

Hereinafter, the present invention 1 and the present invention 2 are collectively referred to as “the present invention” in the description of features common to the present invention 1 and the present invention 2.

The present invention relates to production of a flexible solar cell module in which a solar cell element and a solar cell encapsulant sheet that includes an adhesive layer containing specific components and a fluoropolymer sheet are well adhered to each other by encapsulating the solar cell element with the solar cell encapsulant sheet in a continuous manner by roll-to-roll processing without causing wrinkles and curls.

The present inventors found that in the case that a solar cell encapsulant sheet that includes a fluoropolymer sheet and an adhesive layer containing an ethylene-glycidyl methacrylate copolymer on the fluoropolymer sheet is used to encapsulate a solar cell element, the encapsulation can be accomplished in a comparatively short time by thermocompression bonding at a comparatively low temperature without the need to perform a crosslinking process, and in a continuous manner by roll-to-roll processing, thereby completing the present invention 1.

Also, the present inventors found that in the case that a solar cell encapsulant sheet that includes a fluoropolymer sheet and an adhesive layer containing a specific ethylene-acrylic acid ester-maleic anhydride ternary copolymer on the fluoropolymer sheet is used to encapsulate a solar cell element, the encapsulation can be accomplished in a comparatively short time by thermocompression bonding at a comparatively low temperature without the need to perform a crosslinking process, and in a continuous manner by roll-to-roll processing, thereby completing the present invention 2.

The methods for producing a flexible solar cell module of the present invention include thermocompression bonding of a solar cell encapsulant sheet to at least a light-receiving surface of a solar cell element that includes a flexible substrate and a photoelectric conversion layer on the substrate by pressing them between a pair of heating rolls.

The solar cell encapsulant sheet includes an adhesive layer containing an ethylene-glycidyl methacrylate copolymer (the present invention 1) or an ethylene-acrylic acid ester-maleic anhydride ternary copolymer (the present invention 2) on a fluoropolymer sheet.

The present invention makes use of a solar cell encapsulant sheet that includes such an adhesive layer containing a specific resin to suitably produce flexible solar cell modules by roll-to-roll processing.

The ethylene-glycidyl methacrylate copolymer resin contains 1 to 10% by weight of glycidyl methacrylate units. If the amount of glycidyl methacrylate units is less than 1% by weight, the solar cell encapsulant sheet is less flexible, and has a high melting point. This solar cell encapsulant sheet may therefore exhibit low adhesion when subjected to low-temperature heating, thereby failing to sufficiently encapsulate the solar cell element, and may become prone to wrinkles and curls when subjected to high-temperature heating. If the amount of glycidyl methacrylate units is more than 10% by weight, problems such as difficulty in forming the solar cell encapsulant sheet arise because the solar cell encapsulant sheet tends to become uneven due to heterogeneous crystallization and flow. The preferable lower limit of the amount of glycidyl methacrylate units is 7% by weight, and the preferable upper limit thereof is 9% by weight.

It should be noted that the ethylene-glycidyl methacrylate copolymer resin can be produced by known polymerization techniques.

The ethylene-glycidyl methacrylate copolymer resin may contain units derived from other monomers in addition to the ethylene units and the glycidyl methacrylate units.

The other monomers are not particularly limited, provided that they are copolymerizable with ethylene and glycidyl methacrylate and do not impair the physical properties required to accomplish the present invention. In particular, (meth)acrylates are preferable because their use results in a copolymer resin that provides unimpaired adhesion to a flexible solar cell element in the encapsulation process by roll-to-roll processing. Additionally, (meth)acrylates are preferable in terms of polymerizability and cost.

Among (meth)acrylates, acrylates are preferable, and methyl acrylate, ethyl acrylate, or butyl acrylate is preferable.

The term “(meth)acrylate” herein is intended to include acrylates and methacrylates.

In the case that the ethylene-glycidyl methacrylate copolymer resin includes (meth)acrylate units, the preferable upper limit of the amount of (meth)acrylate units is 15% by weight. If the amount of (meth)acrylate units is more than 15% by weight, the solar cell encapsulant sheet itself has too low a melting point, and when processed into a flexible solar cell module and stored at high temperatures, may fail to maintain its shape, resulting in a reduction in the adhesion of the solar cell encapsulant sheet to the solar cell element and deformation of the solar cell encapsulant sheet. The more preferable upper limit of the amount of (meth)acrylate units is 10% by weight.

The lower limit of the amount of (meth)acrylate units is not particularly limited, provided that the resulting copolymer resin does not affect the adhesion to a flexible solar cell element.

The ethylene-glycidyl methacrylate copolymer resin preferably has a maximum peak temperature (Tm) of 70 to 125° C. as determined from an endothermic curve obtained by differential scanning calorimetry. If the maximum peak temperature (Tm) determined from an endothermic curve is lower than 70° C., the solar cell encapsulant sheet may be less heat resistant. If the maximum peak temperature (Tm) determined from an endothermic curve is higher than 125° C., the solar cell encapsulant sheet may require a longer period of heating in the encapsulation process, leading to lower production efficiency of flexible solar cell modules or failing to sufficiently encapsulate the solar cell element. The maximum peak temperature (Tm) of an endothermic curve is more preferably 80 to 120° C., and still more preferably 85 to 120° C.

The maximum peak temperature (Tm) of an endothermic curve obtained by differential scanning calorimetry is measured in accordance with the method specified in JIS K7121.

The ethylene-glycidyl methacrylate copolymer preferably has a melt flow rate (MFR) of 0.5 g/10 min to 29 g/10 min. If the melt flow rate is less than 0.5 g/10 min, uneven portions may be formed on the solar cell encapsulant sheet in the process of forming the encapsulant sheet, resulting in production of a flexible solar cell module that tends to curl. If the melt flow rate is more than 29 g/10 min, the possibility of drawdown in the process of forming the solar cell encapsulant sheet is high, in other words, it is difficult to form a sheet with an even thickness. This case may also result in production of a flexible solar cell module that tends to curl, or formation of pinholes or the like in the solar cell encapsulant sheet which may cause a resulting solar cell module to entirely lose insulation properties.

The melt flow rate is more preferably 2 g/10 min to 10 g/10 min.

The melt flow rate of the ethylene-glycidyl methacrylate copolymer is measured under a load of 2.16 kg in accordance with ASTM D1238, which is used to measure the melt flow rate of polyethylene resins.

The ethylene-glycidyl methacrylate copolymer preferably has a viscoelastic storage modulus at 30° C. of not more than 2×10⁸ Pa. If the viscoelastic storage modulus at 30° C. is more than 2×10⁸ Pa, the solar cell encapsulant sheet may be less flexible, and therefore may be difficult to handle. Additionally, rapid heating of the solar cell encapsulant sheet may be required to encapsulate the solar cell element with the solar cell encapsulant sheet in the process of producing a flexible solar cell module. If the viscoelastic storage modulus at 30° C. is too low, the solar cell encapsulant sheet may become sticky at room temperature, and therefore may be difficult to handle. Accordingly, the lower limit thereof is preferably 1×10⁷ Pa. The upper limit is more preferably 1.5×10⁸ Pa.

The ethylene-glycidyl methacrylate copolymer preferably has a viscoelastic storage modulus at 100° C. of not more than 5×10⁶ Pa. If the viscoelastic storage modulus at 100° C. is more than 5×10⁶ Pa, the adhesion of the solar cell encapsulant sheet to the solar cell element may be weak.

If the viscoelastic storage modulus at 100° C. is too low, the solar cell encapsulant sheet may significantly flow when pressing force is applied to encapsulate the solar cell element with the solar cell encapsulant sheet in the process of producing a solar cell module. In this case, the thickness of the solar cell encapsulant sheet may become significantly uneven. Accordingly, the lower limit thereof is more preferably 1×10⁴ Pa. The upper limit is more preferably 4×10⁶ Pa.

The viscoelastic storage modulus of the ethylene-glycidyl methacrylate copolymer is measured by a testing method for dynamic properties in accordance with JIS K6394.

The ethylene-acrylic acid ester-maleic anhydride ternary copolymer is a copolymer made from at least three components: ethylene; an acrylic acid ester; and maleic anhydride.

The acrylic acid ester is preferably at least one selected from the group consisting of methyl acrylate, ethyl acrylate, and butyl acrylate in terms of cost and polymerizability.

The ethylene-acrylic acid ester-maleic anhydride ternary copolymer contains 71 to 93% by weight of ethylene units. If the amount of ethylene units is less than 71% by weight, the ternary copolymer has too low a later-described maximum peak temperature (Tm) as determined from an endothermic curve obtained by differential scanning calorimetry method, which leads to low heat resistance of the solar cell encapsulant sheet. This case may result in production of a flexible solar cell module that tends to split when subjected to a high-temperature, high-humidity test or the like. If the amount of ethylene units is more than 93% by weight, the adhesion is weak or the Tm is too high, which increases the temperature of the laminating process. Consequently, wrinkles are likely to occur. The preferable lower limit of the amount of ethylene units is 73% by weight, and the preferable upper limit thereof is 91% by weight.

The ethylene-acrylic acid ester-maleic anhydride ternary copolymer contains 5 to 28% by weight of acrylic acid ester units. If the amount of acrylic acid ester units is less than 5% by weight, the Tm of the ternary copolymer tends to be too high, which necessarily increases the temperature of the bonding process of the solar cell encapsulant sheet. Consequently, wrinkles are likely to occur in the laminating process. Additionally, the solar cell encapsulant sheet may require a longer period of heating in the encapsulation process, leading to lower production efficiency of solar cell modules or failing to sufficiently encapsulate the solar cell. If the amount of acrylic acid ester units is more than 28% by weight, the Tm of the ternary copolymer is too low, which leads to low heat resistance of the solar cell encapsulant sheet. This case may result in production of a flexible solar cell module that tends to split when subjected to a high-temperature, high-humidity test or the like. Additionally, since the adhesive layer may be too sticky at ambient temperature, a stronger force is required to unroll the sheet in the roll-to-roll processing. Therefore, an excessive tensile force is applied to the sheet, which may be a cause of curls and wrinkles. The preferable lower limit of the amount of acrylic acid ester units is 6% by weight, and the preferable upper limit is 26% by weight.

The ethylene-acrylic acid ester-maleic anhydride ternary copolymer contains 0.1 to 4% by weight of maleic anhydride. If the amount of maleic anhydride units is less than 0.1% by weight, the adhesion of the solar cell encapsulant sheet to the solar cell element is weak. If the amount of maleic anhydride units is more than 4% by weight, the solar cell encapsulant sheet is less heat resistant. Also, this case results in production of a flexible solar cell module, the electrodes of which tend to deteriorate due to an acid generated by hydrolysis, and therefore tend to come off when the flexible solar cell module is subjected to a high-temperature, high-humidity test or the like. The preferable lower limit of the amount of maleic anhydride units is 0.3% by weight, and the preferable upper limit is 3.1% by weight.

The ethylene-acrylic acid ester-maleic anhydride ternary copolymer preferably has a maximum peak temperature (Tm) of 60 to 110° C. as determined from an endothermic curve obtained by differential scanning calorimetry. If the maximum peak temperature (Tm) determined from an endothermic curve is lower than 60° C., the solar cell encapsulant sheet may be less heat resistant. If the maximum peak temperature (Tm) determined from an endothermic curve is higher than 110° C., the solar cell encapsulant sheet may require a longer period of heating in the encapsulation process, leading to lower production efficiency of solar cell modules or failing to sufficiently encapsulate the solar cell element.

The maximum peak temperature (Tm) determined from an endothermic curve obtained by differential scanning calorimetry can be determined in accordance with the measurement method specified in JIS K7121.

The ethylene-acrylic acid ester-maleic anhydride ternary copolymer preferably has a melt flow rate (MFR) of 0.5 g/10 min to 50 g/10 min. If the melt flow rate is less than 0.5 g/10 min, uneven portions may be formed on the solar cell encapsulant sheet in the process of forming the encapsulant sheet, resulting in production of a flexible solar cell module that tends to curl. If the melt flow rate is more than 50 g/10 min, the possibility of drawdown in the process of forming the solar cell encapsulant sheet is high, in other words, it is difficult to form a sheet with an even thickness. This case may also result in production of a flexible solar cell module that tends to curl, or formation of pinholes or the like in the solar cell encapsulant sheet which may cause a resulting solar cell module to entirely lose insulation properties. The melt flow rate is more preferably 2 g/10 min to 40 g/10 min.

The melt flow rate is measured under a load of 2.16 kg in accordance with ASTM D1238, which is used to measure the melt flow rate of polyethylene resins.

The adhesive layer preferably contains a silane compound represented by R¹Si(OR²)₃. The presence of the silane compound improves the adhesion between the adhesive layer and the surface of the solar cell element.

R¹ of the silane compound is 3-glycidoxypropyl of the formula (1) or 2-(3,4-epoxycyclohexyl)ethyl of the formula (2), and R² is an alkyl group containing 1 to 3 carbon atoms.

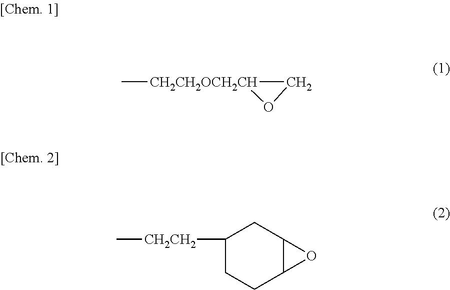

R² is not particularly limited, provided that it is an alkyl group containing 1 to 3 carbon atoms. Examples thereof include methyl, ethyl, and propyl. Preferred is methyl.

Examples of silane compounds represented by R¹Si(OR²)₃ include 3-glycidoxypropyltrimethoxysilane, 3-glycidoxypropyltriethoxysilane, 3-glycidoxypropyltripropoxysilane, 2-(3,4-epoxycyclohexyl)ethyltrimethoxysilane, 2-(3,4-epoxycyclohexyl)ethyltriethoxysilane, and 2-(3,4-epoxycyclohexyl)ethyltripropoxysilane. Preferred is 3-glycidoxypropyltrimethoxysilane.

The silane compound content in the adhesive layer is preferably 0.4 to 15 parts by weight relative to 100 parts by weight of the ethylene-glycidyl methacrylate copolymer.

If the silane compound content is out of the range, the adhesion of the solar cell encapsulant sheet may be weak.

The lower limit of the silane compound content is more preferably 0.4 parts by weight relative to 100 parts by weight of the ethylene-glycidyl methacrylate copolymer, and the upper limit thereof is more preferably 1.5 parts by weight.

The adhesive layer may contain additives that form crosslinks in the process of forming the layer in amounts that do not impair the sheet extrusion efficiency.

Specific examples thereof include amino-based silane coupling agents such as N-2-(aminoethyl)-3-aminopropyltrimethoxysilane.

The adhesive layer may further contain other additives such as photostabilizers, ultraviolet absorbers, and heat stabilizers in amounts that do not impair the physical properties of the adhesive layer.

Examples of methods for forming the adhesive layer include a method involving melting a predetermined ratio (weight basis) of the ethylene-glycidyl methacrylate copolymer or the ethylene-acrylic acid ester-maleic anhydride ternary copolymer and optionally predetermined ratios (weight basis) of additives in an extruder, kneading the mixture, and extruding the mixture into a sheet from the extruder.

The thickness of the adhesive layer is preferably 80 to 700 μm. If the thickness of the adhesive layer is less than 80 μm, the adhesive layer may fail to ensure the insulation properties of flexible solar cell modules. If the thickness of the adhesive layer is more than 700 μm, flexible solar cell modules with impaired flame retardancy or heavy flexible solar cell modules may be provided. Additionally, it is disadvantageous for cost reasons. The thickness of the adhesive layer is more preferably 150 to 400 μm.

In the solar cell encapsulant sheet, the adhesive layer is formed on a fluoropolymer sheet.

The fluoropolymer sheet is not particularly limited, provided that it is excellent in transparency, heat resistance, and flame retardancy. However, the fluoropolymer sheet preferably includes at least one fluoropolymer selected from the group consisting of tetrafluoroethylene-ethylene copolymers (ETFE), ethylene-chlorotrifluoroethylene resins (ECTFE), polychlorotrifluoroethylene resins (PCTFE), polyvinylidene fluoride resins (PVDF), tetrafluoroethylene-perfluoroalkyl vinyl ether copolymers (FAP), polyvinyl fluoride resins (PVF), tetrafluoroethylene-hexafluoropropylene copolymers (FEP), vinylidene fluoride-hexafluoropropylene copolymers (PVDF-HFP), and a mixture of polyvinylidene fluoride and polymethylmethacrylate (PVDF/PMMA).

In particular, the fluoropolymer is more preferably selected from polyvinylidene fluoride resins (PVDF), tetrafluoroethylene-ethylene copolymers (ETFE), and polyvinyl fluoride resins (PVF) because of their better heat resistance and transparency.

The thickness of the fluoropolymer sheet is preferably 10 to 100 μm. If the thickness of the fluoropolymer sheet is less than 10 μm, the fluoropolymer sheet may fail to ensure the insulation properties, and may impair the flame retardancy. If the thickness of the fluoropolymer sheet is more than 100 μm, heavy flexible solar cell modules may be provided, which is disadvantageous for cost reasons. The thickness of the fluoropolymer sheet is more preferably 15 to 80 μm.

The solar cell encapsulant sheet can be formed by integrating the fluoropolymer sheet and the adhesive layer into a laminate. The integration into a laminate can be accomplished by any methods, and examples of integration methods include a method in which the fluoropolymer sheet is formed on one surface of the adhesive layer by extrusion lamination, and a method in which the adhesive layer and the fluoropolymer sheet are formed by coextrusion. In particular, it is preferable to simultaneously form the sheet and the layer as a laminate by coextrusion.

The extrusion temperature in the coextrusion process is preferably higher than the melting point of the fluoropolymer and the ethylene-glycidyl methacrylate copolymer by 30° C. or more and is preferably lower than the decomposition temperature thereof by 30° C. or more.

As described above, the solar cell encapsulant sheet is preferably an integrated laminate formed by simultaneously forming the adhesive layer and the fluoropolymer sheet by coextrusion.

The solar cell encapsulant sheet preferably has an embossed surface. In particular, a surface of the solar cell encapsulant sheet which is to be a light-receiving surface in use is preferably embossed. More specifically, a surface of the fluoropolymer sheet of the solar cell encapsulant sheet which is to be a light-receiving surface of a produced flexible solar cell module is preferably embossed.

The embossed pattern reduces the reflection loss of sunlight, prevents glare, and improves the appearance.

The embossed pattern may consist of peaks and valleys arranged in a regular pattern or peaks and valleys arranged in a random fashion.

The embossed pattern may be formed before or after adhering the solar cell encapsulant sheet to the solar cell element, or may be formed at the same time as adhering to the solar cell element. Preferably, the embossed pattern is formed before adhering to the solar cell element in order to prevent the surface from being non-uniformly embossed and provide a uniformly embossed pattern.

However, in the case that a solar cell encapsulant sheet with an already embossed surface is used to encapsulate a flexible solar cell element by roll-to-roll processing, part of the embossed pattern will be lost during the thermocompression bonding process for encapsulation. For this reason, a commonly used strategy is to emboss the surface of a solar cell encapsulant sheet after encapsulating a flexible solar cell element.

In contrast, even when a solar cell encapsulant sheet with an already embossed surface is used to encapsulate a flexible solar cell element by roll-to-roll processing in accordance with the method for producing a flexible solar cell module of the present invention, it is possible to avoid loss of the embossed pattern. This is presumably because the adhesive layer has a sufficiently high viscoelastic storage modulus as well as sufficient adhesion strength.

The surface of the solar cell encapsulant sheet may be embossed by any methods, and a preferred example of embossing methods is a method in which in the process of simultaneously forming the adhesive layer and the fluoropolymer sheet of the solar cell encapsulant sheet by coextrusion, an embossing roll is used as a chill roll to emboss the surface while cooling the molten resin.

The solar cell element commonly includes a photoelectric conversion layer that generates electrons when receiving light, an electrode layer that draws generated electrons, and a flexible substrate.

The photoelectric conversion layer may be made of, for example, a crystalline semiconductor (e.g. monocrystal silicon, monocrystal germanium, polycrystal silicon, microcrystal silicon), an amorphous semiconductor (e.g. amorphous silicon), a compound semiconductor (e.g. GaAs, InP, AlGaAs, Cds, CdTe, Cu₂S, CuInSe₂, CuInS₂), or an organic semiconductor (e.g. phthalocyanine, polyacetylene).

The photoelectric conversion layer may be a monolayer or a multilayer.

The thickness of the photoelectric conversion layer is preferably 0.5 to 10 μm.

The flexible substrate is not particularly limited, provided that it is flexible and suited for flexible solar cells. Examples thereof include substrates made of a heat resistant resin such as polyimide, polyether ether ketone, or polyethersulfone.

The thickness of the flexible substrate is preferably 10 to 80 μm.

The electrode layer is a layer made of an electrode material.

The electrode layer may be formed on the photoelectric conversion layer, between the photoelectric conversion layer and the flexible substrate, or on the flexible substrate, according to need.

The solar cell element may have two or more electrode layers.

The electrode layer is preferably a transparent electrode when located on the light-receiving surface side because it is required to allow light to pass through. The electrode material is not particularly limited, provided that it is a common transparent electrode material such as a metal oxide. Preferred examples thereof include ITO and ZnO.

In the case that it is not a transparent electrode, it may be a metal (e.g. silver) patterned bus electrode or a metal (e.g. silver) patterned finger electrode, which is used with a bus electrode.

In the case that the electrode layer is located on the back side, it is not necessarily transparent and may be made of a common electrode material. The electrode material, however, is preferably silver.

The solar cell element is produced by any common methods, and examples thereof include a known method in which the photoelectric conversion layer and electrode layers are stacked on the flexible substrate.

The solar cell element may be a long sheet wound into a roll or a rectangular sheet.

The method for producing a flexible solar cell module of the present invention includes thermocompression bonding of the solar cell encapsulant sheet to at least the light-receiving surface of the solar cell element by pressing the solar cell encapsulant sheet and the solar cell element between a pair of heating rolls.

The light-receiving surface of the solar cell element is a surface that generates electric power from received light, and refers to the photoelectric conversion layer-side surface and not to the flexible substrate-side surface.

In the method for producing a flexible solar cell module of the present invention, the thermocompression bonding is preferably accomplished by stacking the solar cell element and the solar cell encapsulant sheet such that the photoelectric conversion layer-side surface of the solar cell element faces the surface of the adhesive layer of the solar cell encapsulant sheet, and pressing them by a pair of heating rolls.

The temperature of the heating rolls used in the pressing process is preferably 80 to 160° C. If the heating roll temperature is lower than 80° C., adhesion failure may occur. If the heating roll temperature is higher than 160° C., wrinkles are likely to occur by the thermocompression bonding. The more preferable heating roll temperature is 90 to 150° C.

The rotation speed of the heating rolls is preferably 0.1 to 10 m/min. If the rotation speed of the heating rolls is less than 0.1 m/min, wrinkles are likely to occur after the thermocompression bonding. If the rotation speed of the heating rolls is more than 10 m/min, adhesion failure may occur. The rotation speed of the heating rolls is more preferably 0.3 to 5 m/min.

Because of the presence of the above-described specific resin in the adhesive layer of the solar cell encapsulant sheet, the method for producing a flexible solar cell module of the present invention allows any crosslinking processes to be omitted, and therefore allows short-term thermocompression bonding. Additionally, the thermocompression bonding can be carried out at low temperatures. Therefore, the method can prevent wrinkles and curls while ensuring sufficient adhesion between the solar cell element and the solar cell encapsulant sheet. Consequently, flexible solar cell modules can be efficiently produced by roll-to-roll processing.

The following description is offered to specifically illustrate the method for producing a flexible solar cell module of the present invention using FIG. 1.

As shown in FIG. 1, a solar cell element A and a solar cell encapsulant sheet B are both long sheets wound into a roll. First, the solar cell element A and the solar cell encapsulant sheet B are unrolled such that the light-receiving surface of the solar cell element A faces the adhesive layer surface of the solar cell encapsulant sheet B, and stacked to form a laminate sheet C.

Subsequently, the laminate sheet C is inserted between a pair of rolls D that are heated to a predetermined temperature, and the solar cell element A and the solar cell encapsulant sheet B are adhered to and integrated with each other by thermocompression bonding in which the laminate sheet C is heated and pressed in the thickness direction. Consequently, the solar cell element A is encapsulated with the solar cell encapsulant sheet B, thereby providing a flexible solar cell module E.

FIG. 2 is a vertical cross-sectional view schematically showing an exemplary solar cell element A used in the method for producing a flexible solar cell module of the present invention, and FIG. 3 is a vertical cross-sectional view schematically showing an exemplary solar cell encapsulant sheet B used in the method for producing a flexible solar cell module of the present invention. As shown in FIG. 2, the solar cell element A includes a photoelectric conversion layer 2 on a flexible substrate 1. It should be noted that electrode layers are omitted because many variations of arrangements thereof are possible. As shown in FIG. 3, the solar cell encapsulant sheet B includes a fluoropolymer sheet 4 and an adhesive layer 3.

FIG. 4 is a vertical cross-sectional view schematically showing an exemplary flexible solar cell module produced by the production method of the present invention.

The photoelectric conversion layer 2-side surface of the solar cell element A is encapsulated with the adhesive layer 3 of the solar cell encapsulant sheet B, as shown in FIG. 4, so that the flexible solar cell module E, an integrated laminate of the solar cell element A and the solar cell encapsulant sheet B, is obtained.

The method for producing a flexible solar cell module of the present invention may further include thermocompression bonding of the solar cell encapsulant sheet to the flexible substrate-side surface of the solar cell element by pressing the solar cell encapsulant sheet and the solar cell element between the heating rolls.

When the flexible substrate-side surface (back surface) of the solar cell element is encapsulated as well as the photoelectric conversion layer-side surface (front surface), the solar cell element is encapsulated more favorably. In this case, the resulting flexible solar cell module can stably generate electric power for a longer time.

The thermocompression bonding of the solar cell encapsulant sheet to the flexible substrate-side surface (back surface) can be accomplished by methods such as a thermocompression bonding method in which the solar cell encapsulant sheet is set such that the adhesive layer of the solar cell encapsulant sheet faces the flexible substrate-side surface (back surface) of the solar cell element, and they are pressed between a pair of heating rolls in the same manner as described above.

In the case that the flexible substrate-side surface of the solar cell element is encapsulated, a solar cell encapsulant sheet including an adhesive layer and a metal plate may be used because light transmitting properties are not required.

Examples of this adhesive layer include the same adhesive layers as those described above for the solar cell encapsulant sheet.

Examples of the metal plate include plates of stainless steel and plates of aluminum.

The thickness of the metal plate is preferably 25 to 800 μm.

In the case that the flexible substrate-side surface (back surface) of the solar cell element is encapsulated with the adhesive layer and the metal plate, the encapsulation can be accomplished by, for example, forming a sheet of the adhesive layer and the metal plate, and thermocompression bonding of the sheet of the adhesive layer and the metal plate to the flexible substrate-side surface (back surface) of the solar cell element, that is, thermocompression bonding of the flexible substrate and the adhesive layer in the manner described above.

The thermocompression bonding process of the solar cell encapsulant sheet or the sheet of the adhesive layer and the metal plate to the flexible substrate-side surface (back surface) of the solar cell element may be carried out before, after, or at the same time as the above-described thermocompression bonding process of the solar cell encapsulant sheet to the light-receiving surface of the solar cell element.

The following description is offered to illustrate, using FIG. 5, one example of the method for producing a flexible solar cell module of the present invention in which the photoelectric conversion layer-side surface (front surface) and the flexible substrate-side surface (back surface) of a solar cell element are simultaneously encapsulated.

Specifically, in addition to a long solar cell element A wound into a roll, two long solar cell encapsulant sheets B wound into rolls are prepared. As shown in FIG. 5, the long solar cell encapsulant sheets B and B are unrolled while the long solar cell element A is also unrolled. The solar cell encapsulant sheets B and B are set such that the adhesive layers of the two sheets face each other, and stacked with the solar cell element A sandwiched therebetween to form a laminate sheet C. The laminate sheet C is inserted between a pair of rolls D and D that are heated to a predetermined temperature, and the solar cell encapsulant sheets B and B are adhered to and integrated with each other by heating and pressing the laminate sheet C in the thickness direction so that the solar cell element A is encapsulated between the solar cell encapsulant sheets B and B. In this manner, a flexible solar cell module F is formed in a continuous manner.

In the method for producing a flexible solar cell module, the pressing of the laminate sheet C in the thickness direction under heating may be performed at the same time as the formation of the laminate sheet C by stacking the solar cell encapsulant sheets B and B with the solar cell element A sandwiched therebetween.

FIG. 6 shows one example of production of a flexible solar cell module in the case of using rectangular solar cell elements.

Specifically, rectangular sheets of a solar cell element A with a predetermined size are prepared instead of the long solar cell element wound into a roll. As shown in FIG. 6, the long solar cell encapsulant sheets B and B are unrolled such that the adhesive layers of these sheets face each other, and the solar cell elements A are delivered between the solar cell encapsulant sheets B and B at regular time intervals. Thus, the solar cell encapsulant sheets B and B are stacked with the solar cell elements A sandwiched therebetween to form a laminate sheet C. The laminate sheet C is inserted between a pair of rolls D and D that are heated to a predetermined temperature, and the solar cell encapsulant sheets B and B are adhered to and integrated with each other by heating and pressing the laminate sheet C in the thickness direction so that the solar cell elements A are encapsulated between the solar cell encapsulant sheets B and B. In this manner, flexible solar cell modules F are formed in a continuous manner.

In the method for producing a flexible solar cell module, the pressing of the laminate sheet C in the thickness direction under heating may be performed at the same time as the formation of the laminate sheet C.

FIGS. 7 and 8 show examples of flexible solar cell modules produced by encapsulating the photoelectric conversion layer-side surface (front surface) and the flexible substrate-side surface (back surface) of a solar cell element by the method for producing a flexible solar cell module of the present invention.

FIG. 7 is a vertical cross-sectional view schematically showing one example of a flexible solar cell module F in which the photoelectric conversion layer 2-side surface and the flexible substrate 1-side surface of a solar cell element A are encapsulated with adhesive layers 3 of solar cell encapsulant sheets B.

FIG. 8 is a vertical cross-sectional view schematically showing one example of a flexible solar cell module G in which the photoelectric conversion layer 2-side surface of a solar cell element A is encapsulated with an adhesive layer 3 of a solar cell encapsulant sheet B, and the flexible substrate 1-side surface is encapsulated with a sheet including an adhesive layer 3 and a metal plate 5.

As described above, the method for producing a flexible solar cell module of the present invention is characterized by encapsulating a solar cell element with a solar cell encapsulant sheet having specific features.

The method can suitably produce flexible solar cell modules in which a solar cell element and a solar cell encapsulant sheet are well adhered to each other by roll-to-roll processing without causing wrinkles and curls.

### Advantageous Effects of Invention

Because of the features described above, the method for producing a flexible solar cell module of the present invention makes it possible to suitably produce flexible solar cell modules in which a solar cell element and a solar cell encapsulant sheet are well adhered to each other by encapsulating a solar cell element by roll-to-roll processing in a continuous manner without the need to perform a crosslinking process and without causing wrinkles and curls.

### BRIEF DESCRIPTION OF DRAWINGS

FIG. 1 is a schematic view showing one example of production by the method for producing a flexible solar cell module of the present invention;

FIG. 2 is a vertical cross-sectional view schematically showing an exemplary solar cell element used in the method for producing a flexible solar cell module of the present invention;

FIG. 3 is a vertical cross-sectional view showing an exemplary solar cell encapsulant sheet used in the method for producing a flexible solar cell module of the present invention;

FIG. 4 is a vertical cross-sectional view showing an exemplary flexible solar cell module produced by the method for producing a flexible solar cell module of the present invention;

FIG. 5 is a schematic view showing one example of production by the method for producing a flexible solar cell module of the present invention;

FIG. 6 is a schematic view showing one example of production by the method for producing a flexible solar cell module of the present invention;

FIG. 7 is a vertical cross-sectional view showing an exemplary flexible solar cell module produced by the method for producing a flexible solar cell module of the present invention;

FIG. 8 is a vertical cross-sectional view showing an exemplary flexible solar cell module produced by the method for producing a flexible solar cell module of the present invention;

FIG. 9 is a schematic view showing an exemplary peak-valley pattern on the surface of a chill roll in an exemplary device for producing solar cell encapsulant sheets;

FIG. 10 is a schematic view showing an exemplary embossed surface of a solar cell encapsulant sheet; and

FIG. 11 is a schematic view showing an exemplary embossing device for solar cell encapsulant sheets.

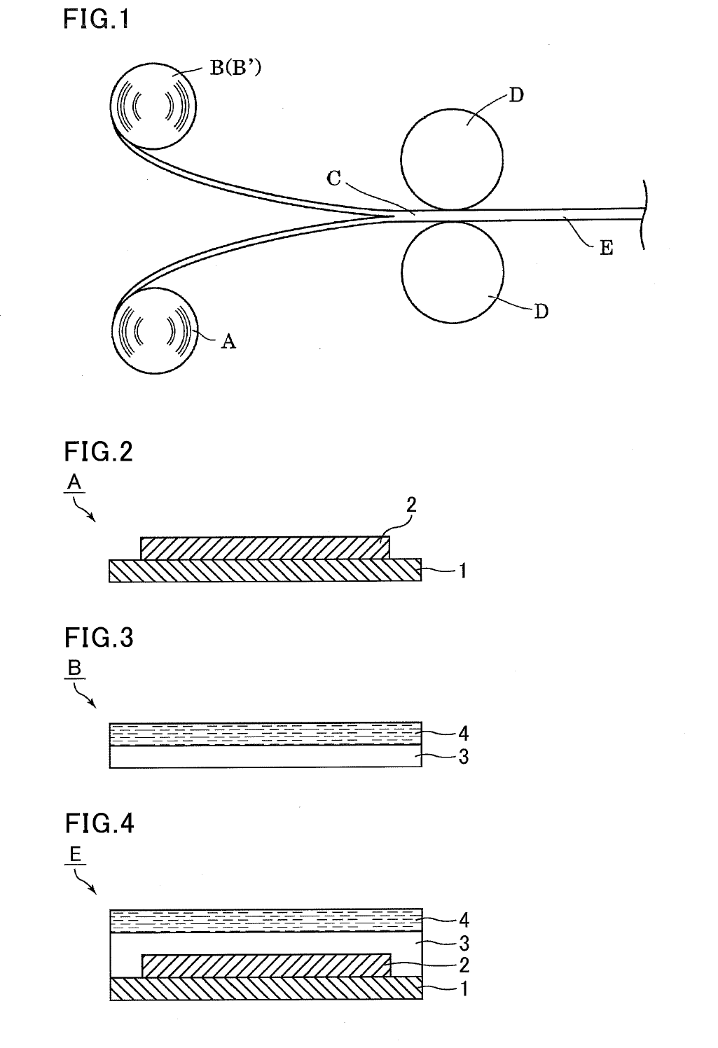

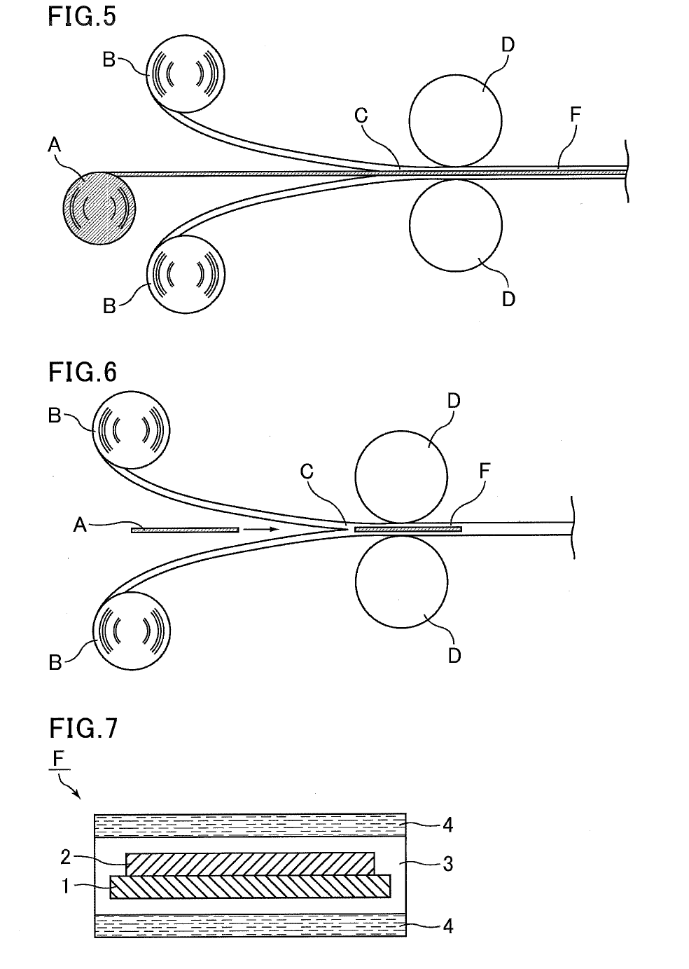

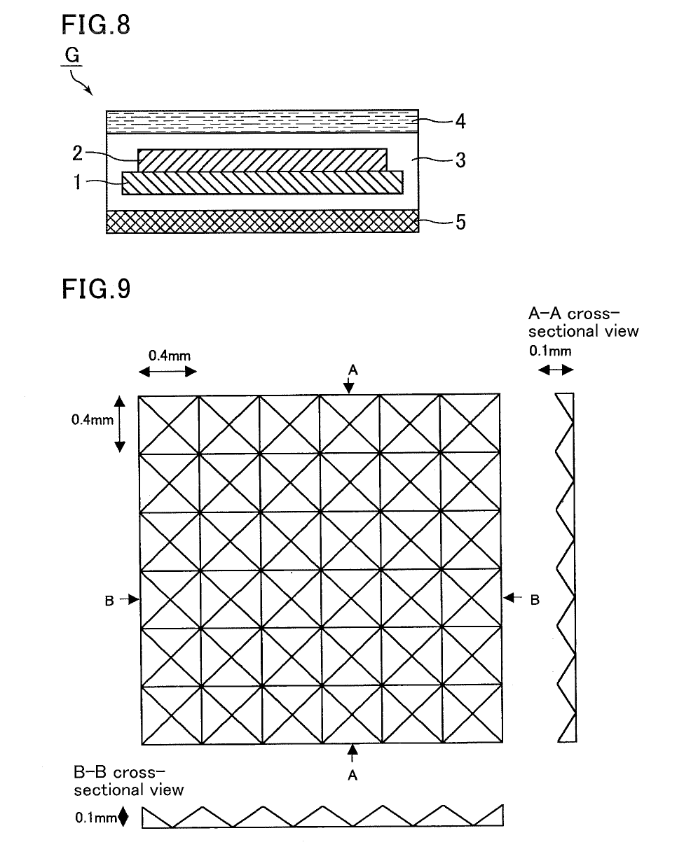

### DESCRIPTION OF EMBODIMENTS

The following examples are offered to illustrate the present invention in more detail, but are not to be construed as limiting the present invention.

### Examples 1 to 12 and Comparative Examples 4 to 6

An adhesive layer composition that contained 100 parts by weight of an ethylene-glycidyl methacrylate copolymer containing predetermined amounts (shown in Tables 1, 2 and 3) of glycidyl methacrylate units, ethylene units and (meth)acrylate units, and a predetermined amount (shown in Tables 1, 2 and 3) of a silane compound selected from 3-glycidoxypropyltrimethoxysilane (trade name: “Z-6040”, available from Dow Corning Toray Co., Ltd.), 2-(3,4-epoxycyclohexyl)ethyltrimethoxysilane (trade name: “Z-6043”, available from Dow Corning Toray Co., Ltd.) and 3-acryloxypropyltrimethoxysilane (trade name: “KBM-5103”, available from Shin-Etsu Chemical Co., Ltd.) was molten and kneaded in a first extruder at 230° C.

Separately, polyvinylidene fluoride (trade name: “Kynar 720”, available from Arkema), a vinylidene fluoride-hexafluoropropylene copolymer (trade name: “Kynar Flex 2800”, available from Arkema), or a mixture of vinylidene fluoride and polymethylmethacrylate (a mixture containing 100 parts by weight of “Kynar 720” (trade name, available from Arkema) and 20 parts by weight of polymethylmethacrylate) was molten and kneaded in a second extruder at 230° C.

The adhesive layer composition and the vinylidene fluoride were supplied to a coalescent die connecting the first extruder and the second extruder where they were contacted, and then extruded from a T die connected to the coalescent die into a sheet that consisted of a 0.3 mm-thick adhesive layer and a 0.03 mm-thick fluoropolymer layer. In this process of forming the sheet by extrusion from the T die, peaks and valleys arranged in a regular pattern as shown in FIG. 10 were formed on the surface of the fluoropolymer layer by a chill roll having a regular pattern of peaks and valleys on the surface as shown in FIG. 9. In this manner, a surface-embossed, long solar cell encapsulant sheet of a predetermined width was obtained as an integrated laminate which consisted of an adhesive layer made of the adhesive layer composition and a fluoropolymer layer on the surface of the adhesive layer.

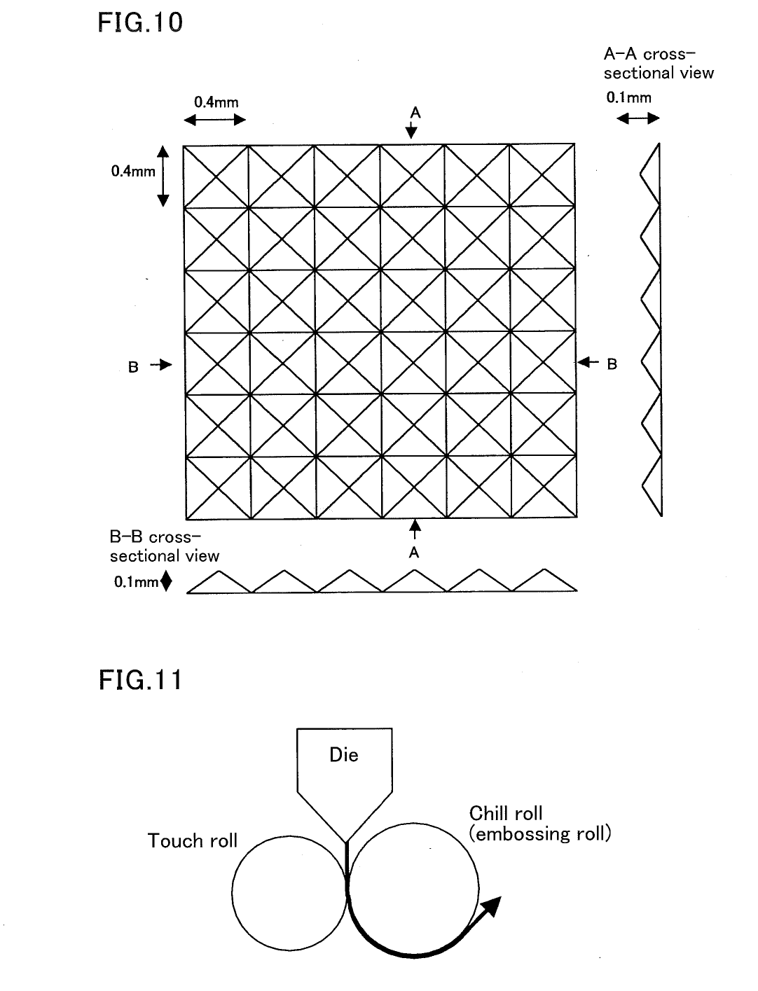

FIG. 11 shows a layout of the embossing roll in a sheet production system.

Tables 1, 2 and 3 show the melt flow rates and the maximum peak temperatures (Tm) determined from endothermic curves obtained by differential scanning calorimetry analysis of the ethylene-glycidyl methacrylate copolymers.

The ethylene-glycidyl methacrylate copolymers used in Examples 1 and 4 and Comparative Example 5 were “Lotader AX8840” commercially available from Arkema.

In Comparative Example 4, a solar cell encapsulant sheet could not be formed because the adhesive layer composition could not be continuously extruded because of too much stress to the extruder.

Subsequently, the solar cell encapsulant sheets obtained above were used to produce flexible solar cell modules in the manner described below. First, as shown in FIG. 6, a rectangular sheet that consisted of a flexible substrate made of a flexible polyimide film and a photoelectric conversion layer made of an amorphous silicon thin film on the flexible substrate was prepared as a solar cell element A, and two rolls of a solar cell encapsulant sheet obtained above were prepared as solar cell encapsulant sheets B.

Next, as shown in FIG. 6, the rolls of the long solar cell encapsulant sheets B and B were unrolled, and the solar cell element A was delivered between the solar cell encapsulant sheets B and B that were set such that their adhesive layers faced each other. The solar cell encapsulant sheets B and B were stacked with the solar cell element A sandwiched therebetween to form a laminate sheet C. The laminate sheet C was delivered between a pair of rolls D and D heated to a temperature shown in Tables 1 to 3, and pressed in the thickness direction under heating so that the solar cell encapsulant sheets B and B were adhered to and integrated with each other with the solar cell element A encapsulated therebetween. In this manner, a flexible solar cell module F was produced.

### Comparative Examples 1, 2

A flexible solar cell module was formed in the same manner as in Example 1, except that a low-density polyethylene (Comparative Example 1) or a modified polyethylene graft modified with maleic anhydride (Comparative Example 2) was used instead of using an ethylene-glycidyl methacrylate copolymer, and that the temperature of the rolls used for encapsulation was changed as shown in Table 1.

### Comparative Example 3

A flexible solar cell module was formed in the same manner as in Example 1, except that EVA was used instead of using an ethylene-glycidyl methacrylate copolymer, and that the temperature of the rolls used for encapsulation was changed as shown in Table 1.

### Comparative Example 5

A flexible solar cell module was formed in the same manner as in Example 1, except that polyethylene terephthalate was used instead of using a fluoropolymer.

The flexible solar cell modules thus obtained were analyzed for occurrence of wrinkles and curls, peeling strength, and resistance to high-temperature, high-humidity conditions in the following manner. Tables 1, 2 and 3 show the results.

### <Occurrence of Wrinkles>

The flexible solar cell modules obtained above were visually evaluated for occurrence of wrinkles and scored based on the following criteria. The ratings of 4 or higher are regarded as being acceptable.

5: No wrinkles were observed.
4: The number of 0.5-mm or shorter winkles observed per unit length (m) was 1.
3: The number of 0.5-mm or shorter winkles observed per unit length (m) was 2 to 4.
2: The number of 0.5-mm or shorter winkles observed per unit length (m) was 5 or more.
1: Large wrinkles with a length of 0.5 mm or more were observed.

### <Occurrence of Curls>

A 500 mm×500 mm piece of each flexible solar cell module was placed on a flat surface, and measured for the height of an edge part curling up from the flat surface.

⊚ (Double circle): less than 20 mm
∘ (Circle): 20 mm or more and less than 25 mm
Δ (Triangle): 25 mm or more and less than 35 mm
x (Cross): 35 mm or more

### <Peeling Strength>

Each flexible solar cell module obtained above was measured for the peeling strength by peeling the solar cell encapsulant sheet from the flexible substrate of the solar cell in accordance with JIS K6854.

### <Resistance to High-Temperature, High-Humidity Conditions>

Each flexible solar cell module obtained above was left at 85° C. and a relative humidity of 85%, and measured for the time from when the solar cell module was allowed to stand in this environment to when the solar cell encapsulant sheet began to come off from the flexible substrate of the solar cell module.

The flexible solar cell modules of Comparative Examples 1 to 4 resulted in 0 hour in the evaluation of the resistance to high-temperature, high-humidity conditions because coming off was observed before the peeling strength evaluation.

TABLE 1

| | | Example 1 | Example 2 | Example 3 | Example 4 | Example 5 | Example 6 |
|---|---|---|---|---|---|---|---|
| Fluoropolymer | | PVDF | PVDF | PVDF | PVDF | PVDF | PVDF |
| Copolymer | Ethylene units | 92 | 95 | 90 | 92 | 93 | 78 |
| | (% by weight) | | | | | | |
| | Glycidyl methacrylate units | 8 | 5 | 10 | 8 | 7 | 8 |
| | (% by weight) | | | | | | |
| | Methyl acrylate units | 0 | 0 | 0 | 0 | 0 | 14 |
| | (% by weight) | | | | | | |
| | Ethyl acrylate units | 0 | 0 | 0 | 0 | 0 | 0 |
| | (% by weight) | | | | | | |
| | Amount (parts by weight) | 100 | 100 | 100 | 100 | 100 | 100 |
| | Total amount of maleic | 0 | 0 | 0 | 0 | 0 | 0 |
| | anhydride (% by weight) | | | | | | |
| | MFR (g/10 min) | 5 | 4 | 6 | 5 | 6 | 6 |
| | Tm (° C.) | 105 | 70 | 104 | 105 | 88 | 71 |

| | | | | | | |
|---|---|---|---|---|---|---|
| 3-Glycidoxypropyltrimethoxysilane | 0.6 | 0.6 | 0.6 | 0 | 0.3 | 0.3 |
| (parts by weight) | | | | | | |
| 2-(3,4-Epoxycyclohexyl) | 0 | 0 | 0 | 0 | 0 | 0 |
| ethyltrimethoxysilane | | | | | | |
| (parts by weight) | | | | | | |
| 3-Acryloxypropyltrimethoxysilane | 0 | 0 | 0 | 0.6 | 0 | 0 |
| (parts by weight) | | | | | | |
| Roll temperature (° C.) | 110 | 110 | 110 | 110 | 150 | 150 |
| Rotation speed (m/min) | 0.5 | 0.5 | 0.5 | 0.5 | 2 | 2 |
| Wrinkles | 5 | 5 | 4 | 4 | 5 | 5 |
| Curls | ⊚ | ⊚ | ◯ | ⊚ | ⊚ | ⊚ |
| Peeling strength | 70 N/cm | 60 N/cm or higher | 70 N/cm or higher | 18 N/cm | 70 N/cm or higher | 60 N/cm or higher |
| Resistance to high temperature and | 3000 H or longer | 1000 H | 3000 H or longer | 1000 H | 3000 H or longer | 2000 H or longer |
| high humidity | | | | | | |

TABLE 2

| | | Example 7 | Example 8 | Example 9 | Example 10 | Example 11 | Example 12 |
|---|---|---|---|---|---|---|---|
| Fluoropolymer | | PVDF—HFP | PVDF/PMMA | PVDF—HFP | PVDF/PMMA | PVDF | PVDF |
| Copolymer | Ethylene units | 84 | 86 | 88 | 92 | 99 | 99 |
| | (% by weight) | | | | | | |
| | Glycidyl methacrylate | 8 | 8 | 8 | 8 | 1 | 3 |
| | units (% by weight) | | | | | | |
| | Methyl acrylate units | 8 | 6 | 0 | 0 | 0 | 0 |
| | (% by weight) | | | | | | |
| | Ethyl acrylate units | 0 | 0 | 4 | 0 | 0 | 0 |
| | (% by weight) | | | | | | |
| | Amount (parts by weight) | 100 | 100 | 100 | 100 | 100 | 100 |
| | Total amount of maleic | 0 | 0 | 0 | 0 | 0 | 0 |
| | anhydride (% by weight) | | | | | | |
| | MFR (g/10 min) | 6 | 6 | 6 | 5 | 2 | 3 |
| | Tm (° C.) | 83 | 90 | 83 | 105 | 90 | 70 |

| | | | | | | |
|---|---|---|---|---|---|---|
| 3-Glycidoxypropyltrimethoxysilane | 0.3 | 0.3 | 0.3 | 0 | 0.6 | 0.6 |
| (parts by weight) | | | | | | |
| 2-(3,4-Epoxycyclohexyl) | 0 | 0 | 0 | 0.3 | 0 | 0 |
| ethyltrimethoxysilane | | | | | | |
| (parts by weight) | | | | | | |
| 3-Acryloxypropyltrimethoxysilane | 0 | 0 | 0 | 0 | 0 | 0 |
| (parts by weight) | | | | | | |
| Roll temperature (° C.) | 150 | 150 | 150 | 110 | 150 | 150 |
| Rotation speed (m/min) | 2 | 2 | 2 | 0.5 | 0.5 | 0.5 |
| Wrinkles | 5 | 5 | 5 | 5 | 5 | 5 |
| Curls | ⊚ | ⊚ | ⊚ | ⊚ | ⊚ | ⊚ |
| Peeling strength | 70 N/cm or | 70 N/cm or | 70 N/cm or | 70 N/cm | 50 N/cm or | 60 N/cm or |
| | higher | higher | higher | | higher | higher |
| Resistance to high temperature and | 3000 H or | 3000 H or | 3000 H or | 3000 H or | 3000 H or | 3000 H or |
| high humidity | longer | longer | longer | longer | longer | longer |

TABLE 3

| | | Comparative | Comparative | Comparative | Comparative | Comparative | Comparative |
|---|---|---|---|---|---|---|---|
| | | Example 1 | Example 2 | Example 3 | Example 4 | Example 5 | Example 6 |
| Fluoropolymer | | PVDF | PVDF | PVDF | PVDF | PET | PVDF |
| Copolymer | Ethylene units | 100 | 100 | EVA | 87 | 92 | 100 |
| | (% by weight) | | | (VA content: | | | |
| | | | | 28%) | | | |
| | Glycidyl methacrylate | 0 | 0 | | 13 | 8 | 0 |
| | units (% by weight) | | | | | | |
| | Methyl acrylate units | 0 | 0 | | 0 | 0 | 0 |
| | (% by weight) | | | | | | |
| | Ethyl acrylate units | 0 | 0 | | 0 | 0 | 0 |
| | (% by weight) | | | | | | |
| | Amount (parts by weight) | 100 | 100 | | 100 | 100 | 100 |
| | Total amount of maleic | 0 | 0.01 | | 0 | 0 | 0.01 |
| | anhydride (% by weight) | | | | | | |
| | MFR (g/10 min) | 2.5 | 0.5 | 30 | 0.05 | 5 | 0.5 |
| | Tm (° C.) | 115 | 120 | 67 | 130 | 105 | 120 |

| | | | | | | |
|---|---|---|---|---|---|---|
| 3-Glycidoxypropyltrimethoxysilane | 0.6 | 0.6 | 0.6 | 0.6 | 0.6 | 0.6 |
| (parts by weight) | | | | | | |
| 2-(3,4-Epoxycyclohexyl) | 0 | 0 | 0 | 0 | 0 | 0 |
| ethyltrimethoxysilane | | | | | | |
| (parts by weight) | | | | | | |
| 3-Acryloxypropyltrimethoxysilane | 0 | 0 | 0 | 0 | 0 | 0 |
| (parts by weight) | | | | | | |
| Roll temperature (° C.) | 135 | 135 | 90 | 135 | 110 | 150 |
| Rotation speed (m/min) | 0.5 | 0.5 | 0.5 | 0.5 | 0.5 | 0.5 |
| Wrinkles | 2 | 1 | Pores created | — | 5 | 1 |
| | | | by foaming | | | |
| Curls | x | x | x | — | x | x |
| Peeling strength | Already | Already | Already | — | 5 N/cm or | 5 N/cm or |
| | separated | separated | separated | | lower | lower |
| Resistance to high temperature and | 0 H | 0 H | 0 H | — | Shorter than | Shorter than |
| high humidity | | | | | 100 H | 100 H |

### Examples 13 to 22, Comparative Examples 7 to 15

An adhesive layer composition that contained 100 parts by weight of an ethylene-acrylic acid ester-maleic anhydride ternary copolymer resin including predetermined amounts of units as shown in Tables 4 and 5 (in the tables, EA represents ethyl acrylate, MA represents methyl acrylate, and BA represents butyl acrylate), and a predetermined amount (shown in Tables 4 and 5) of a silane compound selected from 3-glycidoxypropyltrimethoxysilane (trade name: “Z-6040”, available from Dow Corning Toray Co., Ltd.) and 2-(3,4-epoxycyclohexyl)ethyltrimethoxysilane (trade name: “Z-6043”, available from Dow Corning Toray Co., Ltd.) was molten and kneaded in a first extruder at 250° C.

Separately, a predetermined fluoropolymer (shown in Tables 4 and 5) selected from polyvinylidene fluoride (trade name: “Kynar 720”, available from Arkema), a vinylidene fluoride-hexafluoropropylene copolymer (trade name: “Kynar Flex 2800”, available from Arkema), and a mixture of vinylidene fluoride and polymethylmethacrylate (a mixture containing 100 parts by weight of “Kynar 720” (trade name, available from Arkema) and 20 parts by weight of polymethylmethacrylate) was molten and kneaded in a second extruder at 230° C.

The adhesive layer composition and the fluoropolymer were supplied to a coalescent die connecting the first extruder and the second extruder where they were contacted, and then extruded from a T die connected to the coalescent die into a sheet that consisted of a 0.3 mm-thick adhesive layer and a 0.03 mm-thick fluoropolymer layer. In this process of forming the sheet by extrusion from the T die, peaks and valleys arranged in a regular pattern as shown in FIG. 10 were formed on the surface of the fluoropolymer layer using a chill roll having a regular pattern of peaks and valleys on the surface as shown in FIG. 9. In this manner, a surface-embossed, long solar cell encapsulant sheet of a predetermined width was obtained as an integrated laminate which consisted of an adhesive layer made of the adhesive layer composition and a fluoropolymer layer on the surface of the adhesive layer.

FIG. 11 shows a layout of the embossing roll in a sheet production system.

Tables 4 and 5 show the melt flow rates and maximum peak temperatures (Tm) determined from endothermic curves obtained by differential scanning calorimetry analysis of the ternary copolymer resins.

Subsequently, the solar cell encapsulant sheets were used to produce flexible solar cell modules in the manner described below. First, as shown in FIG. 6, a rectangular sheet that consisted of a flexible substrate made of a flexible polyimide film and a photoelectric conversion layer made of an amorphous silicon thin film on the flexible substrate was prepared as a solar cell element A, and two rolls of the solar cell encapsulant sheet obtained above were prepared as solar cell encapsulant sheets B.

Next, as shown in FIG. 6, the rolls of the long solar cell encapsulant sheets B and B were unrolled, and the solar cell element A was delivered between the solar cell encapsulant sheets B and B that were set such that their adhesive layers faced each other. The solar cell encapsulant sheets B and B were stacked with the solar cell element A sandwiched therebetween to form a laminate sheet C. The laminate sheet C was delivered between a pair of rolls D and D heated to a temperature shown in Tables 4 and 5, and pressed in the thickness direction under heating so that the solar cell encapsulant sheets B and B were adhered to and integrated with each other with the solar cell element A encapsulated therebetween. In this manner, a flexible solar cell module F was produced.

The flexible solar cell modules thus obtained were analyzed for occurrence of wrinkles and curls, peeling strength, and resistance to high-temperatures, high-humidity conditions by the above-described methods. Tables 4 and 5 show the results.

TABLE 4

| | | Example 13 | Example 14 | Example 15 | Example 16 | Example 17 | Example 18 |
|---|---|---|---|---|---|---|---|
| Extrusion temperature | | 250° C. | 250° C. | 250° C. | 250° C. | 250° C. | 250° C. |
| Fluoropolymer | | PVDF | PVDF | PVDF | PVDF | PVDF | PVDF |
| Ethylene- | Ethylene units | 77.2 | 73.7 | 90.9 | 77.2 | 73.7 | 90.9 |
| acrylic acid ester- | (% by weight) | | | | | | |
| maleic anhydride | Acrylic acid ester | EA | MA | BA | EA | MA | BA |
| ternary copolymer | units (% by weight) | 20 | 26 | 6 | 20 | 26 | 6 |
| | Maleic anhydride | 2.8 | 0.3 | 3.1 | 2.8 | 0.3 | 3.1 |
| | units (% by weight) | | | | | | |
| | MFR (g/10 min) | 20 | 8 | 5 | 20 | 8 | 5 |
| | Tm (° C.) | 80 | 62 | 107 | 80 | 62 | 107 |
| EVA | Vinyl acetate | — | — | — | — | — | — |
| | (% by weight) | | | | | | |
| | MFR (g/10 min) | — | — | — | — | — | — |
| | Tm (° C.) | — | — | — | — | — | — |

| | | | | | | |
|---|---|---|---|---|---|---|
| 3-Glycidoxypropyltrimethoxysilane | 0.5 | 0.5 | 0.5 | 0 | 0 | 0 |
| (parts by weight) | | | | | | |
| 2-(3,4-Epoxycyclohexyl) | 0 | 0 | 0 | 0 | 0 | 0 |
| ethyltrimethoxysilane | | | | | | |
| (parts by weight) | | | | | | |
| Roll temperature (° C.) | 90 | 120 | 120 | 90 | 120 | 120 |
| Rotation speed (m/min) | 0.5 | 0.5 | 0.5 | 0.5 | 0.5 | 0.5 |
| Wrinkles | 5 | 5 | 4 | 5 | 5 | 4 |
| Curls | ◯ | ⊚ | ◯ | ◯ | ⊚ | ◯ |
| Peeling strength | 70 N/cm or | 70 N/cm or | 70 N/cm or | 45 N/cm or | 40 N/cm or | 45 N/cm or |
| | higher | higher | higher | higher | higher | higher |
| Resistance to high temperature and | 3000 H or | 3000 H or | 3000 H or | 3500 H | 2000 H | 3000 H |
| high humidity | longer | longer | longer | | | |

| | | Example 19 | Example 20 | Example 21 | Example 22 |
|---|---|---|---|---|---|
| Extrusion temperature | | 250° C. | 230° C. | 250° C. | 230° C. |
| Fluoropolymer | | PVDF—HFP | PVDF/PMMA | PVDF—HFP | PVDF/PMMA |
| Ethylene- | Ethylene units | 89.7 | 73.7 | 91.2 | |
| acrylic acid ester- | (% by weight) | | | | |
| maleic anhydride | Acrylic acid ester | MA | EA | EA | BA |
| ternary copolymer | units (% by weight) | 10 | 26 | 6 | 25 |
| | Maleic anhydride | 0.3 | 0.3 | 2.8 | 0.3 |
| | units (% by weight) | | | | |
| | MFR (g/10 min) | 5 | 5 | 8 | 5 |
| | Tm (° C.) | 100 | 70 | 100 | 80 |
| EVA | Vinyl acetate | — | — | — | — |
| | (% by weight) | | | | |
| | MFR (g/10 min) | — | — | — | — |
| | Tm (° C.) | — | — | — | — |

| | | | | |
|---|---|---|---|---|
| 3-Glycidoxypropyltrimethoxysilane | 0 | 0 | 0 | 0 |
| (parts by weight) | | | | |
| 2-(3,4-Epoxycyclohexyl) | 0 | 0 | 0.5 | 0.5 |
| ethyltrimethoxysilane | | | | |
| (parts by weight) | | | | |
| Roll temperature (° C.) | 120 | 120 | 120 | 120 |
| Rotation speed (m/min) | 0.5 | 0.5 | 0.5 | 0.5 |
| Wrinkles | 4 | 5 | 4 | 5 |
| Curls | ◯ | ◯ | ◯ | ◯ |
| Peeling strength | 70 N/cm or | 45 N/cm or | 70 N/cm or | 45 N/cm or |
| | higher | higher | higher | higher |
| Resistance to high temperature and | 3000 H or | 2000 H | 3000 H or | 3500 H |
| high humidity | longer | | longer | |

TABLE 5

| | | Comparative | Comaprative | Comparative | Comparative | Comparative |
|---|---|---|---|---|---|---|
| | | Example 7 | Example 8 | Example 9 | Example 10 | Example 11 |
| Extrusion temperature | | 250° C. | 250° C. | 250° C. | 250° C. | 250° C. |
| Fluoropolymer | | PVDF | PVDF | PVDF | PVDF | PVDF |
| Ethylene- | Ethylene units | — | 98.5 | 68 | 91 | 85 |
| acrylic acid ester- | (% by weight) | | | | | |
| maleic anhydride | Acrylic acid ester | — | EA | EA | EA | EA |
| ternary copolymer | units (% by weight) | — | 1 | 30 | 3 | 15 |
| | Maleic anhydride | — | 0.5 | 2 | 6 | 0 |
| | units (% by weight) | | | | | |
| | MFR (g/10 min) | — | 2 | 7 | 4 | 7 |
| | Tm (° C.) | — | 126 | 57 | 105 | 97 |
| EVA | Vinyl acetate | 27 | — | — | — | — |
| | (% by weight) | | | | | |
| | MFR (g/10 min) | 30 | — | — | — | — |
| | Tm (° C.) | 70 | — | — | — | — |

| | | | | | |
|---|---|---|---|---|---|
| 3-Glycidoxypropyltrimethoxysilane | 0.5 | 0 | 0 | 0 | 0 |
| (parts by weight) | | | | | |
| 2-(3,4-Epoxycyclohexyl) | 0 | 0 | 0 | 0 | 0 |
| ethyltrimethoxysilane | | | | | |
| (parts by weight) | | | | | |
| Roll temperature (° C.) | 85 | 140 | 80 | 120 | 90 |
| Rotation speed (m/min) | 0.5 | 0.5 | 0.5 | 0.5 | 0.5 |
| Wrinkles | 1 | 1 | 4 | 3 | 3 |
| Curls | x | x | x | Δ | Δ |
| Peeling strength | 70 N/cm or higher | 10 N/cm | 30 N/cm | 55 N/cm | 7 N/cm |
| Resistance to high temperature and | 1000 H | 2500 H | 1500 H | 1000 H | 48 H |
| high humidity | | | | | |

| | | Comparative | Comparative | Comparative | Comparative |
|---|---|---|---|---|---|
| | | Example 12 | Example 13 | Example 14 | Example 15 |
| Extrusion temperature | | 250° C. | 250° C. | 250° C. | 250° C. |
| Fluoropolymer | | PVDF | PVDF | PVDF | PVDF |
| Ethylene- | Ethylene units | 97.7 | 69.7 | 97.7 | 69.7 |
| acrylic acid ester- | (% by weight) | | | | |
| maleic anhydride | Acrylic acid ester | MA | MA | BA | BA |
| ternary copolymer | units (% by weight) | 2 | 30 | 2 | 30 |
| | Maleic anhydride | 0.3 | 0.3 | 0.3 | 0.3 |
| | units (% by weight) | | | | |
| | MFR (g/10 min) | 5 | 10 | 5 | 10 |
| | Tm (° C.) | 120 | 60 | 126 | 61 |
| EVA | Vinyl acetate | — | — | — | — |
| | (% by weight) | | | | |
| | MFR (g/10 min) | — | — | — | — |
| | Tm (° C.) | — | — | — | — |

| | | | | |
|---|---|---|---|---|
| 3-Glycidoxypropyltrimethoxysilane | 0 | 0 | 0 | 0 |
| (parts by weight) | | | | |
| 2-(3,4-Epoxycyclohexyl) | 0 | 0 | 0 | 0 |
| ethyltrimethoxysilane | | | | |
| (parts by weight) | | | | |
| Roll temperature (° C.) | 140 | 90 | 140 | 90 |
| Rotation speed (m/min) | 0.5 | 0.5 | 0.5 | 0.5 |
| Wrinkles | 1 | 3 | 1 | 3 |
| Curls | Δ | Δ | Δ | Δ |
| Peeling strength | 10 N/cm | 30 N/cm | 10 N/cm | 30 N/cm |
| Resistance to high temperature and | 1000 H | 1000 H | 1000 H | 1000 H |
| high humidity | | | | |

### INDUSTRIAL APPLICABILITY

The method for producing a flexible solar cell module of the present invention makes it possible to suitably produce flexible solar cell modules in which a solar cell element and a solar cell encapsulant sheet are well adhered to each other by roll-to-roll processing without causing wrinkles and curls.

### REFERENCE SIGNS LIST

A Solar cell element
B, B′ Solar cell encapsulant sheet
C Laminate sheet
D Roll
E, F, G Flexible solar cell module
1 Flexible substrate
2 Photoelectric conversion layer
3 Adhesive layer
4 Fluoropolymer sheet
5 Metal plate

1. A method for producing a flexible solar cell module, comprising thermocompression bonding of a solar cell encapsulant sheet to at least a light-receiving surface of a solar cell element that comprises a flexible substrate and a photoelectric conversion layer on the flexible substrate by pressing the solar cell encapsulant sheet and the solar cell element together between a pair of heating rolls,
the solar cell encapsulant sheet comprising a fluoropolymer sheet and an adhesive layer on the fluoropolymer sheet, the adhesive layer comprising an ethylene-glycidyl methacrylate copolymer resin,
the ethylene-glycidyl methacrylate copolymer resin comprising 1 to 10% by weight of glycidyl methacrylate units.

2. The method for producing a flexible solar cell module according to claim 1,
wherein the ethylene-glycidyl methacrylate copolymer resin further comprises (meth)acrylate units.

3. A method for producing a flexible solar cell module, comprising thermocompression bonding of a solar cell encapsulant sheet to at least a light-receiving surface of a solar cell element that comprises a flexible substrate and a photoelectric conversion layer on the flexible substrate by pressing the solar cell encapsulant sheet and the solar cell element together between a pair of heating rolls,
the solar cell encapsulant sheet comprising a fluoropolymer sheet and an adhesive layer on the fluoropolymer sheet, the adhesive layer comprising an ethylene-acrylic acid ester-maleic anhydride ternary copolymer,
the ethylene-acrylic acid ester-maleic anhydride ternary copolymer comprising: 71 to 93% by weight of ethylene units; 5 to 28% by weight of acrylic acid ester units; and 0.1 to 4% by weight of maleic anhydride units.

4. The method for producing a flexible solar cell module according to claim 1,
wherein the fluoropolymer sheet comprises at least one fluoropolymer selected from the group consisting of tetrafluoroethylene-ethylene copolymers, ethylene-chlorotrifluoroethylene resins, polychlorotrifluoroethylene resins, polyvinylidene fluoride resins, tetrafluoroethylene-perfluoroalkyl vinyl ether copolymers, polyvinyl fluoride resins, tetrafluoroethylene-hexafluoropropylene copolymers, vinylidene fluoride-hexafluoropropylene copolymers, and a mixture of polyvinylidene fluoride and polymethylmethacrylate.

5. The method for producing a flexible solar cell module according to claim 1,
wherein the adhesive layer further comprises a silane compound represented by R¹Si(OR²)₃ wherein R¹ is 3-glycidoxypropyl or 2-(3,4-epoxycyclohexyl)ethyl group; and R² is an alkyl group containing 1 to 3 carbon atoms, and
the silane compound is present in an amount of 0.4 to 15 parts by weight relative to 100 parts by weight of the ethylene-glycidyl methacrylate copolymer resin.

6. The method for producing a flexible solar cell module according to claim 1,
wherein the solar cell encapsulant sheet has an embossed surface.

7. The method for producing a flexible solar cell module according to claim 1,
wherein the solar cell encapsulant sheet is an integrated laminate of the fluoropolymer sheet and the adhesive layer that are simultaneously formed and stacked by coextrusion.
